(19) United States
(12) Patent Application Publication
(10) Pub. No.: US 2026/0081612 A1
(43) Pub. Date: Mar. 19, 2026

(54) SYSTEMS AND METHODS FOR ERROR DETECTION IN AN ANALOG-TO-DIGITAL CONVERTER (ADC)

(71) Applicant: Microchip Technology Incorporated, Chandler, AZ (US)

(72) Inventors: Andrei Bucsa, Gilbert, AZ (US); Stephen Bowling, Chandler, AZ (US)

(73) Assignee: Microchip Technology Incorporated, Chandler, AZ (US)

(21) Appl. No.: 19/172,754

(22) Filed: Apr. 8, 2025

Related U.S. Application Data
(60) Provisional application No. 63/694,333, filed on Sep. 13, 2024.

(51) Int. Cl. H03M 1/10

(52) U.S. Cl. CPC H03M 1/1071

(57) ABSTRACT

A system includes an analog-to-digital converter (ADC) circuitry to convert an analog input signal to a first digital output signal, and convert a complement of the analog input signal to a second digital output signal, wherein the complement of the analog input signal comprises a difference between a reference voltage and the analog input signal, and error detection circuitry to identify an invalid conversion of the analog input signal based on the first digital output signal and the second digital output signal.

### RELATED PATENT APPLICATION

This application claims priority to commonly owned United States Provisional Patent Application No. 63/694,333 filed Sep. 13, 2024, the entire contents of which are hereby incorporated by reference for all purposes.

### TECHNICAL FIELD

The present disclosure relates to systems and methods for detecting errors in an analog-to-digital converter (ADC) circuit.

### BACKGROUND

An analog-to-digital converter (ADC) converts an analog signal to a digital signal, for example to allow digital circuits to utilize analog sensor measurements, e.g., to monitor temperature, sound, light, movement, or other parameters. The hardware circuitry of an ADC may be referred to as an ADC IP (intellectual property) block.

The functioning of an ADC (e.g., analog to digital conversation accuracy) may be affected by various factors, including upsetting events like: induced currents, electrostatic discharge, a neutron or alpha particle upset, or aging of the ADC circuitry, for example. Thus, an ADC may be monitored over time to ensure proper functioning, e.g., accuracy. Such monitoring is common in safety-critical applications (e.g., products and industries having an SIL, ASIL, or DAL safety integrity level classification), which may implement periodic validation of ADC performance according to defined performance criteria.

Conventional techniques for monitoring ADC functioning include periodic testing using two independent and parallel data conversion paths, often using diverse ADC architectures, to ensure conversion values are consistent as a linear function of analog input. Such testing may involve applying known stimuli to the respective inputs of the independent and parallel ADC paths (typically using diverse ADC architectures) and comparing the results to each other and/or to expected values to detect potential errors.

Conventional approaches may suffer from various drawbacks or limitations. For example, conventional testing involves either software resources (which often complicate system development) or a hardware implementation for testing by a state machine, which renders the IP block unavailable during the testing. As another example, providing diverse ADC architectures in a chipset in a manner that ensures effective insulation of the processing paths may be costly.

There is a need for improved systems and methods for monitoring of ADC performance, e.g., to detect conversion failures (invalid conversions).

### SUMMARY

The present disclosure provides systems and methods for monitoring of ADC performance, e.g., to detect conversion failures. Examples of the present disclosure may provide continuous and (software) transparent IP block run-time self-testing based on LFD (latent failure detection) to identify potential ADC malfunctions that may develop due to system aging or stress, for example.

Example systems and methods disclosed herein may be suitable for A/D conversion in critical applications in which undetected malfunctions can lead to catastrophic failures, for example for monitoring a critical pressure or monitoring a car wheel angular position.

Some examples provide an ADC topology including parallel processing paths using a primary ADC1 and a secondary (replica) ADC2 that convert an analog input signal using an analog equivalent of “digital one's complement,” wherein ADC1 processes the analog input signal, and ADC2 processes a “complement” of the analog input signal defined by a difference between the analog input signal and a reference voltage. The expected conversion results of the two processing paths are complementary at the bit level, with the second processing path outputting the complement (opposite) value (0 or 1) for each respective bit. This allows for a simple validation of the output, e.g., using an XOR operation.

As the validation is performed at bit level (e.g., using XOR), quality statistics may be generated in parallel, and may include generating sets of “granular results,” for example by selectively disregarding a certain numbers of low significant bits (through a selective AND operation) to achieve conversion validation. The input signal quality can be asserted, on multiple granularities, at each end of acquisition cycle, with no latency and further processing, by accumulating the error magnitude, and by classifying and storing the results in (related) counters. Error data may be accumulated as linear or rolling average data, for example, based on the relevant logic topology.

Thus, disclosed systems and methods may provide simple logic to achieve error statistics for acquired data at a high ADC speed (with an active direct memory access (DMA) mechanism) with no need for processor resource involvement. Some examples provide real-time identification and mitigation of a temporary (induced) malfunction caused by an external event, or identification of a permanent malfunction related to component aging or operating stress, with no involvement of the main CPU.

Additionally, by choosing certain values for the inputs, the ADC dynamic range can remain the same for composed structure, and testing can be performed during normal operation without needing peripheral testing time, e.g., during device booting or/and processor (e.g., microcontroller core) IDLE time.

In some examples, the processing by ADC1 and ADC2 may be interlaced and temporally offset by delaying the sampling by a half period of a sampling clock, e.g., to achieve processing temporal diversity, and to avoid loss in the maximum achievable sampling clock.

In some examples, ADC1 and ADC2 comprise two identical ADC IP blocks arranged orthogonally to each other such that event upsets (e.g., induced currents, electrostatic discharges, or neutron or alpha particle upsets) will affect the ADC IP blocks differently, thus resulting in detectable conversion errors.

One aspect provides a system including (a) analog-to-digital converter (ADC) circuitry to convert an analog input signal to a first digital output signal, and convert a complement of the analog input signal to a second digital output signal, wherein the complement of the analog input signal comprises a difference between a reference voltage and the analog input signal, and (b) error detection circuitry to identify an invalid conversion of the analog input signal based on the first digital output signal and the second digital output signal.

In some examples, the ADC circuitry comprises a first ADC block to convert the analog input signal to the first digital output signal, and a second ADC block, connected in parallel with the first ADC block, to convert the complement of the analog input signal to the second digital output signal.

In some examples, the first ADC block has a first ADC input and a second ADC input, and the second ADC block has a first ADC input and a second ADC input. The first ADC input of the first ADC block is connected to the analog input signal, and the second ADC input of the first ADC block is connected to ground, wherein the first ADC block is configured to convert a first differential voltage between the analog input signal and ground to the first digital output signal. The first ADC input of the second ADC block is connected to a non-ground reference voltage, and the second ADC input of the second ADC block is connected to the analog input signal, wherein the second ADC block is configured to convert a second differential voltage between the non-ground reference voltage and the analog input signal to the second digital output signal, the second differential voltage defining the complement of the analog input signal.

In some examples, the first ADC block and the second ADC block are arranged physically orthogonal to each other.

In some examples, the first ADC block and the second ADC block have the same structural layout but arranged physically orthogonal to each other.

In some examples, the ADC circuitry comprises an ADC block to (a) perform a first conversion to convert the analog input signal to the first digital output signal and (b) in series with the first conversion, perform a second conversion to convert the complement of the analog input signal to the second digital output signal.

In some examples, the ADC block has a first ADC input and a second ADC input, and the ADC circuitry comprises circuitry to switch between (a) a first ADC input configuration for the first conversion, wherein the first ADC input configuration includes connecting the first ADC input to the analog input signal and connecting the second ADC input to ground, wherein the first conversion comprises converting a first differential voltage between the analog input signal and ground, and (b) a second ADC input configuration for the second conversion, wherein the second ADC input configuration includes connecting the first ADC input to a non-ground reference voltage and connecting the second ADC input to the analog input signal, wherein the second conversion comprises converting a second differential voltage between the non-ground reference voltage and the analog input signal to the second digital output signal, the second differential voltage defining the complement of the analog input signal.

In some examples, the ADC circuitry comprises a multiplexer to switch between the first ADC input configuration for the first conversion and the second ADC input configuration for the second conversion.

In some examples, the error detection circuitry comprises circuitry to perform a bit-level conversion analysis including comparing respective bits of the first digital output signal with corresponding bits of the second digital output signal, and identify the invalid conversion of the analog input signal based on the bit-level conversion analysis.

In some examples, the error detection circuitry comprises an XOR circuitry to compare respective bits of the first digital output signal with corresponding bits of the second digital output signal, wherein an output of 0 from the XOR circuitry indicates a bit-level conversion error.

In some examples, the error detection circuitry comprises circuitry to (a) perform a bit-level conversion analysis for multiple bits of the first digital output signal and multiple corresponding bits of the second digital output signal, wherein the bit-level conversion analysis for each respective bit of the multiple bits of the first digital output signal includes (i) comparing a respective bit of the first digital output signal with a corresponding bit of the second digital output signal, and (ii) based on the comparison, identifying a bit-level conversion error if the value of the respective bit of the first digital output signal is the same as the value of the corresponding bit of the second digital output signal, and (b) identify the invalid conversion of the analog input signal based on the bit-level conversion analysis.

In some examples, the error detection circuitry comprises circuitry to, when performing the bit-level conversion analysis, disregard a defined number of least significant bits (LSB) of the first digital output signal and corresponding bits of the second digital output signal.

In some examples, the error detection circuitry comprises an XOR circuitry to compare respective bits of the first digital output signal with corresponding bits of the second digital output signal.

In some examples, the first digital output signal comprises a first n-bit signal, the second digital output signal comprises a second n-bit signal, and the error detection circuitry comprises circuitry to identify a k-bit conversion error based on the first digital output signal and the second digital output signal, determine whether the k-bit conversion error exceeds a defined error threshold, and identify the invalid conversion of the analog input signal based on determining the k-bit conversion error exceeds the defined error threshold.

In some examples, the system includes circuitry to implement a time delay between converting the analog input signal to the first digital output signal and converting the complement of the analog input signal to the second digital output signal. In some examples, the time delay is a half period of a sampling clock cycle.

In some examples, the system includes multiple error counters for multiple different bits of different 2ⁿ weights, wherein each error counter counts a number of conversion errors identified for a respective bit of a respective 2ⁿ weight.

Another aspect provides a method, including receiving an analog input signal at analog-to-digital converter (ADC) circuitry, performing a first conversion, by the ADC circuitry, to convert the analog input signal to a first digital output signal, performing a second conversion, by the ADC circuitry, to convert a complement of the analog input signal to a second digital output signal, wherein the complement of the analog input signal comprises a difference between a reference voltage and the analog input signal, and identifying, by error detection circuitry, an invalid conversion of the analog input signal based on the first digital output signal and the second digital output signal.

In some examples, the ADC circuitry includes a first ADC block and a second ADC block connected in parallel with the first ADC block, and the method includes performing the first conversion by the first ADC block to convert the analog input signal to the first digital output signal, and performing the second conversion by the second ADC block to convert a second ADC block to convert the complement of the analog input signal to the second digital output signal.

In some examples, the ADC circuitry includes a first ADC block and a second ADC block connected in parallel with the first ADC block.

In some examples, the first ADC block has a first ADC input and a second ADC input, and the second ADC block has a first ADC input and a second ADC input. The first ADC input of the first ADC block is connected to the analog input signal, and the second ADC input of the first ADC block is connected to ground, wherein performing the first conversion by the first ADC block comprises the first ADC block converting a first differential voltage between the analog input signal and ground to the first digital output signal. The first ADC input of the second ADC block is connected to a non-ground reference voltage, and the second ADC input of the second ADC block is connected to the analog input signal, wherein performing the second conversion by the second ADC block comprises the second ADC block converting a second differential voltage between the non-ground reference voltage and the analog input signal to the second digital output signal, the second differential voltage defining the complement of the analog input signal.

In some examples, the ADC circuitry comprises an ADC block, and the method includes the ADC block performing the first conversion to convert the analog input signal to a first digital output signal. and in series with the first conversion, the ADC block performing the second conversion to convert a second ADC block to convert the complement of the analog input signal to the second digital output signal.

In some examples, the ADC block has a first ADC input and a second ADC input, and the method includes switching between (a) a first ADC input configuration for the first conversion, wherein the first ADC input configuration includes connecting the first ADC input to the analog input signal and connecting the second ADC input to ground, wherein the first conversion comprises converting a first differential voltage between the analog input signal and ground, and (b) a second ADC input configuration for the second conversion, wherein the second ADC input configuration includes connecting the first ADC input to a non-ground reference voltage and connecting the second ADC input to the analog input signal, wherein the second conversion comprises converting a second differential voltage between the non-ground reference voltage and the analog input signal to the second digital output signal, the second differential voltage defining the complement of the analog input signal.

In some examples, identifying the invalid conversion of the analog input signal includes performing a bit-level conversion analysis including comparing respective bits of the first digital output signal with corresponding bits of the second digital output signal, and identifying the invalid conversion of the analog input signal based on the bit-level conversion analysis.

In some examples, the method includes using an XOR circuitry to compare respective bits of the first digital output signal with corresponding bits of the second digital output signal, and identifying a bit-level conversion error based on output of 0 from the XOR circuitry.

In some examples, identifying the invalid conversion of the analog input signal comprises (a) performing a bit-level conversion analysis for multiple bits of the first digital output signal and multiple corresponding bits of the second digital output signal, wherein the bit-level conversion analysis for each respective bit of the multiple bits of the first digital output signal includes (i) comparing a respective bit of the first digital output signal with a corresponding bit of the second digital output signal, and (ii) based on the comparison, identifying a bit-level conversion error if the value of the respective bit of the first digital output signal is the same as the value of the corresponding bit of the second digital output signal, and (b) identifying the invalid conversion of the analog input signal based on the bit-level conversion analysis.

In some examples, performing the bit-level conversion analysis includes disregard a defined number of least significant bits (LSB) of the first digital output signal and corresponding bits of the second digital output signal.

In some examples, the first digital output signal comprises a first n-bit signal, the second digital output signal comprises a second n-bit signal, and the method includes identifying a k-bit conversion error based on the first digital output signal and the second digital output signal, determining whether the k-bit conversion error exceeds a defined error threshold, and identifying the invalid conversion of the analog input signal based on determining the k-bit conversion error exceeds the defined error threshold.

In some examples, the method includes implementing a time delay between performing the first conversion and performing the second conversion. In some examples, the time delay is a half period of a sampling clock cycle.

In some examples, the method includes maintaining and updating multiple error counters for multiple different bits of different 2ⁿ weights, wherein each error counter counts a number of conversion errors identified for a respective bit of a respective 2ⁿ weight.

Another aspect provides a system, including (a) a first ADC having a first ADC input and a second ADC input, wherein the first ADC input of the first ADC block is connected to an analog input signal, and the second ADC input of the first ADC block is connected to ground, wherein the first ADC block is configured to convert a first differential voltage between the analog input signal and ground to a first digital output signal, (b) a second ADC block having a first ADC input and a second ADC input, wherein the first ADC input of the second ADC block is connected to a non-ground reference voltage, and the second ADC input of the second ADC block is connected to the analog input signal, wherein the second ADC block is configured to convert a second differential voltage between the non-ground reference voltage and the analog input signal to a second digital output signal, and (c) error detection circuitry to identify an invalid conversion of the analog input signal based on the first digital output signal and the second digital output signal.

In some examples, the non-ground reference voltage has a greater magnitude than the analog input signal.

In some examples, the error detection circuitry comprises circuitry to perform a bit-level conversion analysis including comparing respective bits of the first digital output signal with corresponding bits of the second digital output signal, and identify the invalid conversion of the analog input signal based on the bit-level conversion analysis.

In some examples, the error detection circuitry comprises an XOR circuitry to compare respective bits of the first digital output signal with corresponding bits of the second digital output signal, wherein an output of 0 from the XOR circuitry indicates a bit-level conversion error.

In some examples, the error detection circuitry comprises circuitry to (a) perform a bit-level conversion analysis for multiple bits of the first digital output signal and multiple corresponding bits of the second digital output signal, wherein the bit-level conversion analysis for each respective bit of the multiple bits of the first digital output signal includes (i) comparing a respective bit of the first digital output signal with a corresponding bit of the second digital output signal, and (ii) based on the comparison, identifying a bit-level conversion error if the value of the respective bit of the first digital output signal is the same as the value of the corresponding bit of the second digital output signal, and (b) identify the invalid conversion of the analog input signal based on the bit-level conversion analysis.

### BRIEF DESCRIPTION OF THE DRAWINGS

Example aspects of the present disclosure are described below in conjunction with the figures, in which:

FIG. 1 shows an example system for identifying analog-to-digital conversion errors using a first ADC to convert an analog input signal and a second ADC to convert a complement of the analog input signal;

FIGS. 2A and 2B show two example implementations of the system of FIG. 1, wherein the first and second ADCs are embodied by a pair of ADC IP blocks;

FIGS. 3A-3C show example circuitry for analyzing digital output signals output by the disclosed ADC circuitry, and computing cumulative error statistics;

FIGS. 4A-4C show example circuitry for analyzing digital output signals output by the disclosed ADC circuitry, and computing rolling average error statistics;

FIG. 5A illustrates another example implementation of the system of FIG. 1, wherein the first and second ADCs are embodied by a single ADC block performing both a conversion of an analog input signal and a conversion of a complement of the analog input signal; and

FIG. 5B illustrates a process flow implemented by the example system shown in FIG. 5A.

It should be understood the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

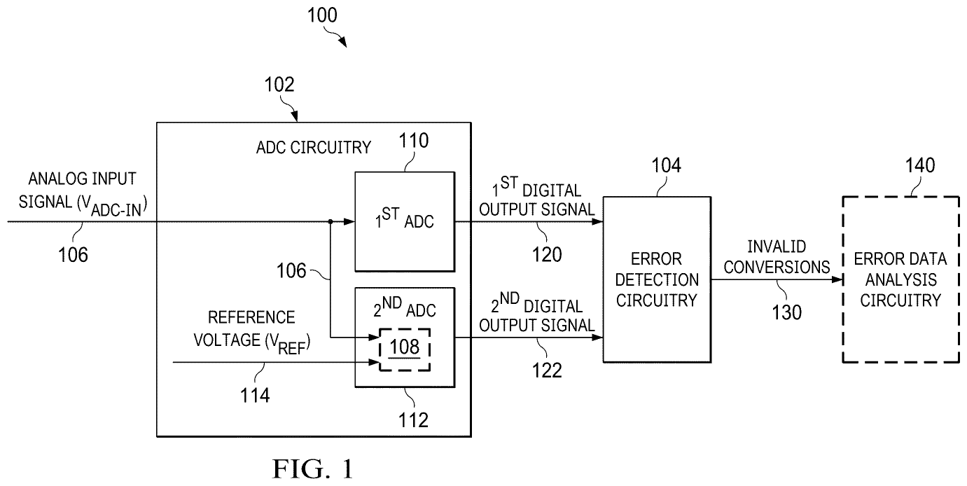

FIG. 1 shows an example system 100 for identifying analog-to-digital conversion errors using a first ADC to convert an analog input signal and a second ADC to convert a complement of the analog input signal. The example system 100 includes analog-to-digital converter (ADC) circuitry 102 and error detection circuitry 104. The ADC circuitry 102 includes (a) a first ADC 110 to convert an analog input signal 106 (V_{ADC_IN}) to a first n-bit digital output signal 120, and (b) a second ADC 112 to convert an analog input signal complement 108, comprising a difference between the analog input signal 106 and a reference voltage 114 (V_{REF}), to a second n-bit digital output signal 122. As discussed below, the reference voltage 114 may be the same as or different from a reference voltage supplied to ADCs 110 and 112 to define the maximum voltage the ADC circuitry 102 can convert. The error detection circuitry 104 includes circuitry to identify invalid conversions of the analog input signal 106 based on the first digital output signal 120 and second digital output signal 122, as discussed below.

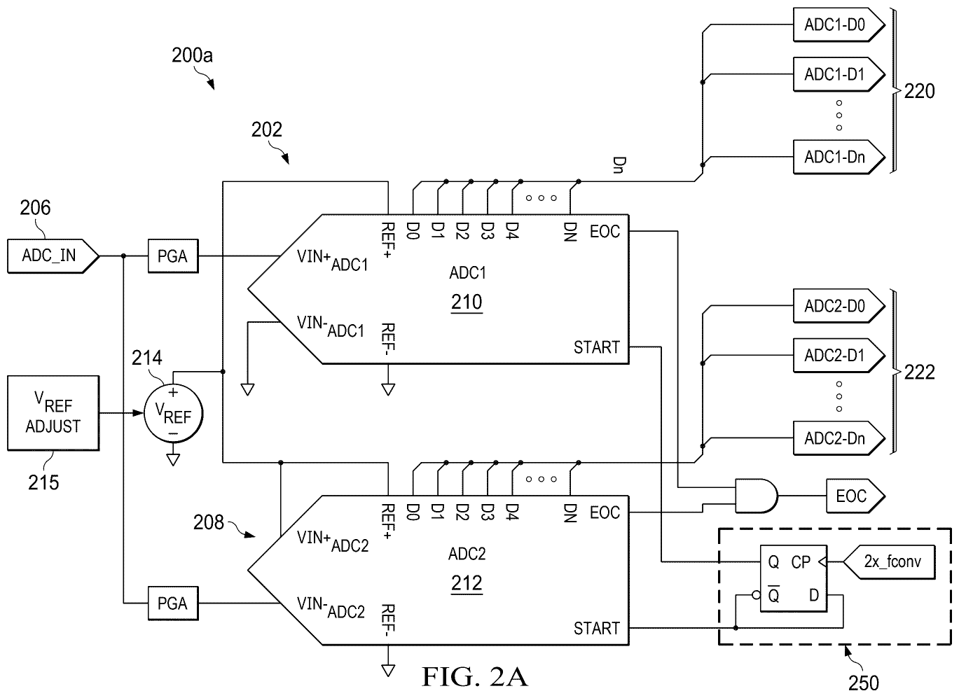

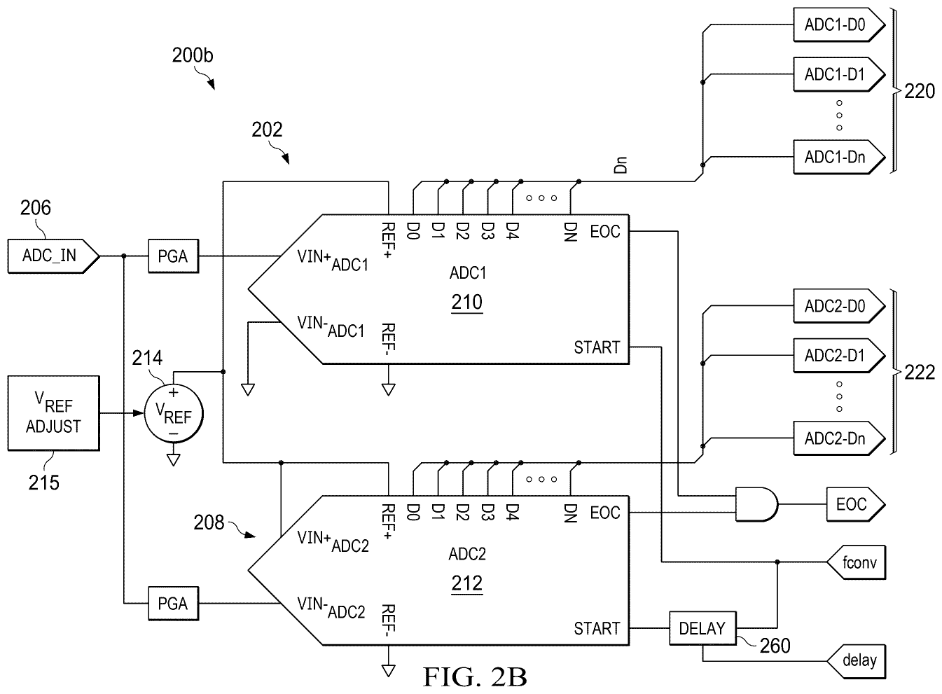

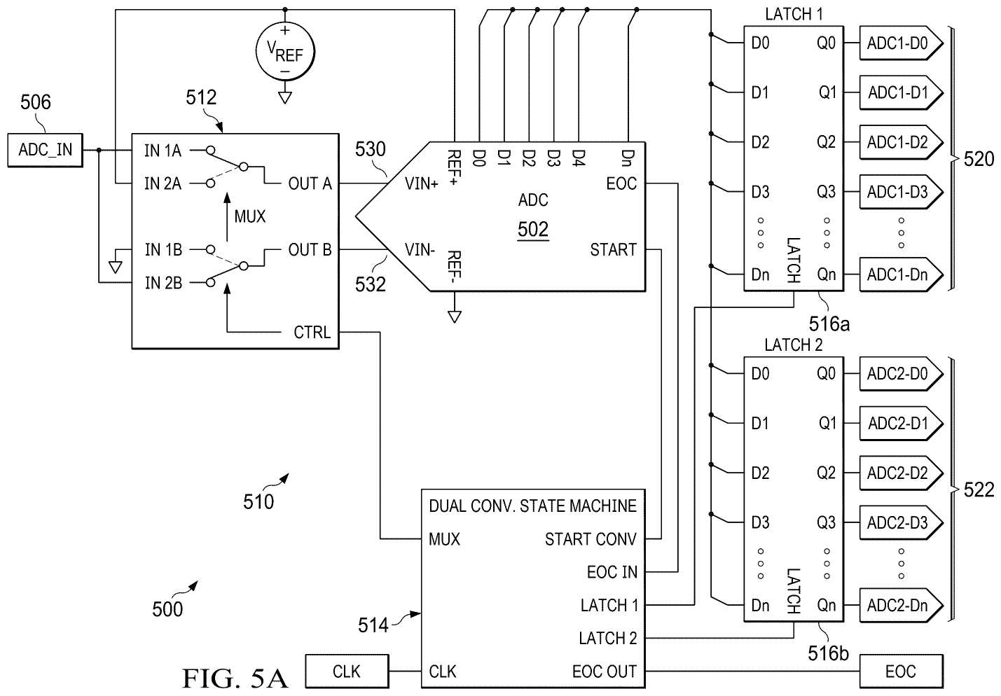

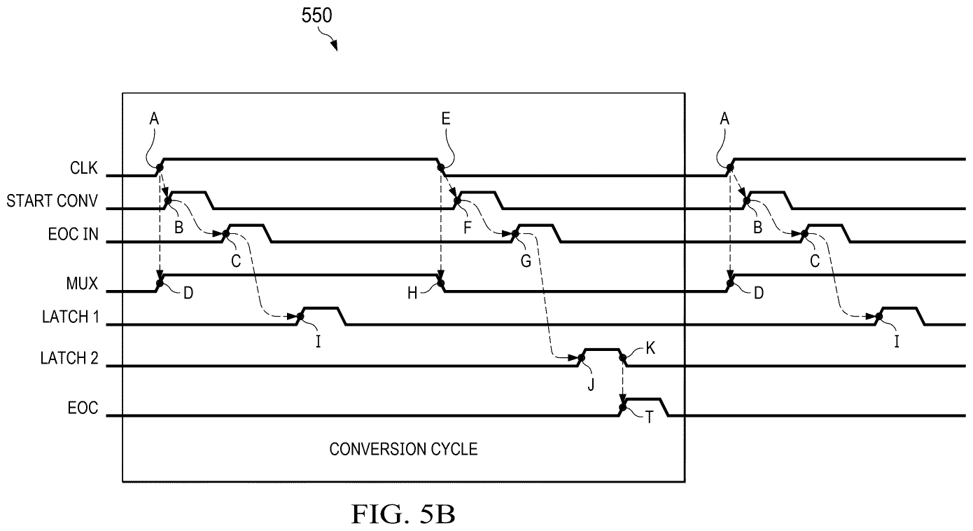

In some examples, the first ADC 110 and second ADC 112 represent a first ADC block 110 and a separate second ADC block 112, e.g., as shown in the example systems of FIGS. 2A and 2B discussed below. In other examples, the first ADC 110 and second ADC 112 In other examples, the first ADC 110 and second ADC 112 represent two ADC processes performed in succession by a single ADC block, e.g., as shown in the example system of FIGS. 5A-5B discussed below.

When both ADCs 110 and 112 function properly (i.e., without conversion errors), the first digital output signal 120 (i.e., the converted analog input signal 106) and the second digital output signal 122 (i.e., the converted analog input signal complement 108) are complementary to each other at the bit level, such that for each respective bit of the n-bit output signals 120 and 122, if the first output signal 120 indicates a 0, then the complementary second output signal 122 indicates a 1, and vice versa. Thus, the outputs of ADCs 110 and 112 can be validated using an XOR operation for each bit of the first digital output signal 120 and second digital output signal 122. Accordingly, in some examples, error detection circuitry 104 comprises XOR circuitry to compare respective bits of the first n-bit digital output signal 120 with corresponding bits of the second n-bit digital output signal 122, wherein each output of 1 from the XOR circuitry indicates correct conversion by ADC circuitry 102, while each output of 0 from the XOR circuitry indicates a bit-level conversion error by ADC circuitry 102, indicated in FIG. 1 as an invalid conversions 130.

The disclosed conversion validation architecture using (and comparing) two conversion paths, namely the first path (via ADC 110) to convert the input signal 106 and the second path (via ADC 112) to convert the complement 108 of the input signal 206 may be unaffected by or tolerant to variations or imprecision in the reference voltage 114 (V_{REF}), as the conversion validation is not a function of the reference voltage 114. Accordingly, the functioning of the ADC circuitry 102 may be analyzed independent of the reference voltage 114; that is, any fault or other issue affecting one of the conversion paths (e.g., anything concerning ADC circuitry 102, for example input circuitry, the ADC 110 or 112, or an associated multiplexer, programmable-gain amplifier (PGA), ADC state machine, or other circuitry) is unlikely to similarly affect the other conversion path, thereby allowing detection of such faults or issues with the functioning of the ADC circuitry 102.

In addition, ADC circuitry 102 may include circuitry to dynamically adjust the reference voltage 114 (V_{REF}) to accommodate different input voltages V_{ADC_IN}, e.g., as compared with certain conventional ADC systems that require gain adjustment of a PGA associated with a conventional ADC. For example, during a first time, ADC circuitry 102 may set or adjust V_{REF} to 250 mV to accommodate an input signal swing of 250 mV, and then during a second time, set or adjust V_{REF} to 2.5V to accommodate an input signal swing of 2.5V, which is equivalent to a PGA gain of 10 but without using PGA gain adjustment.

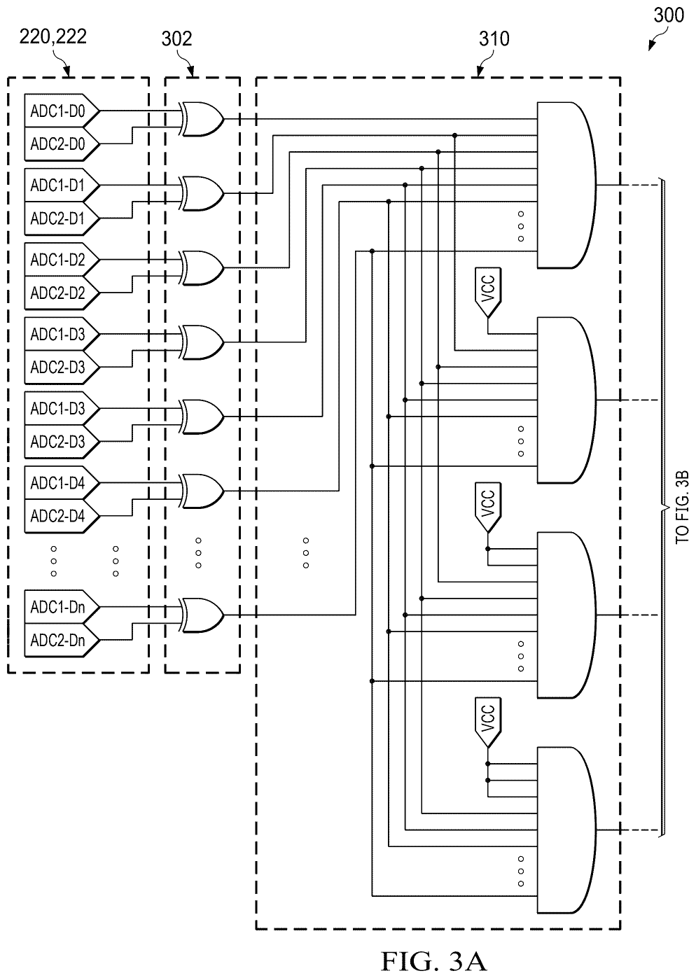

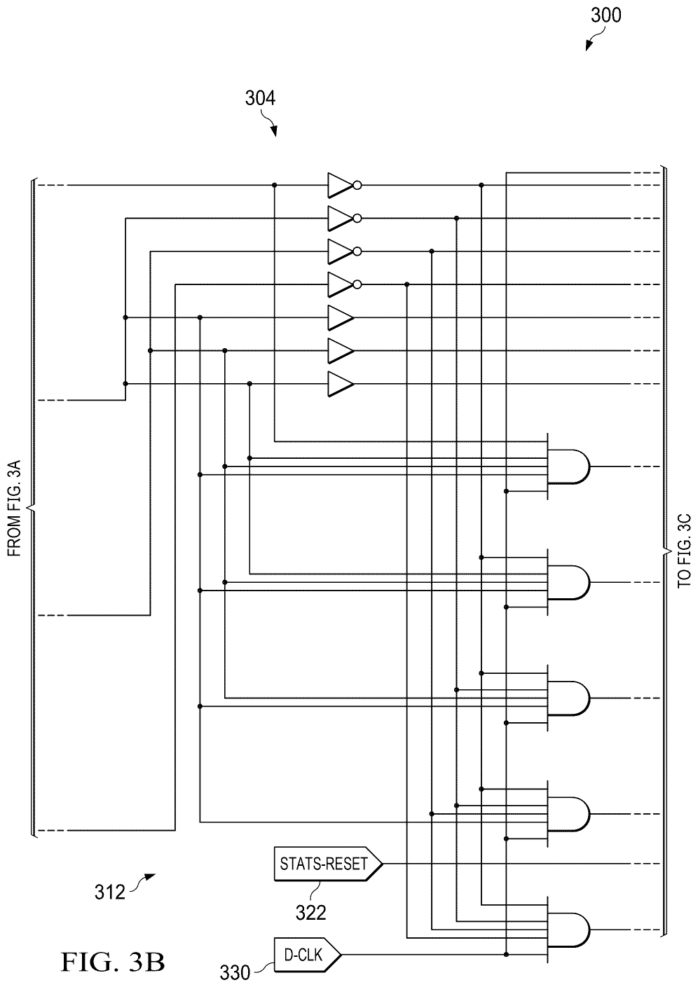

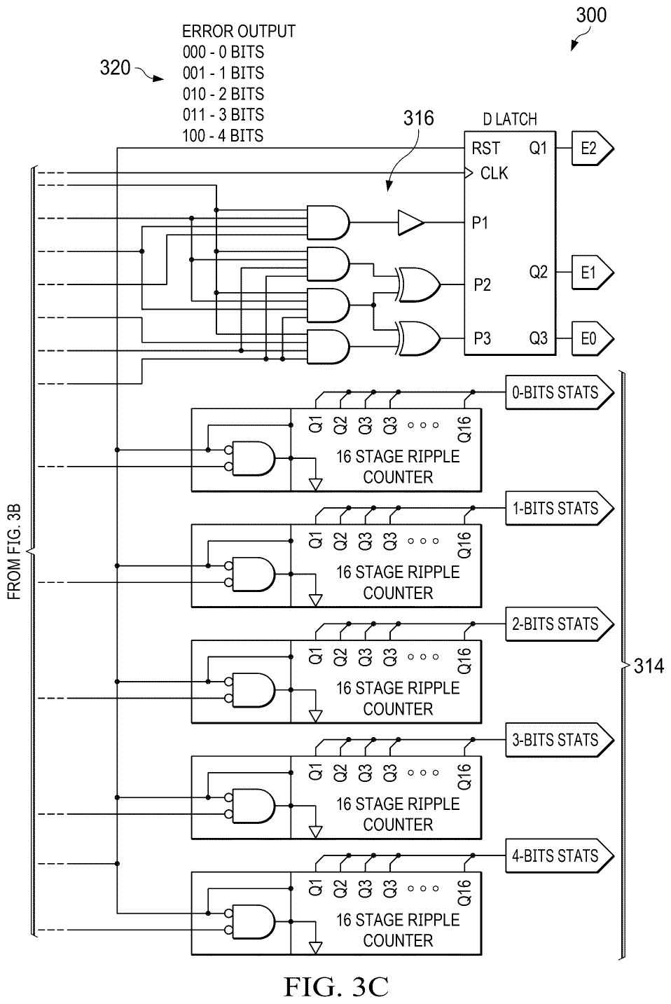

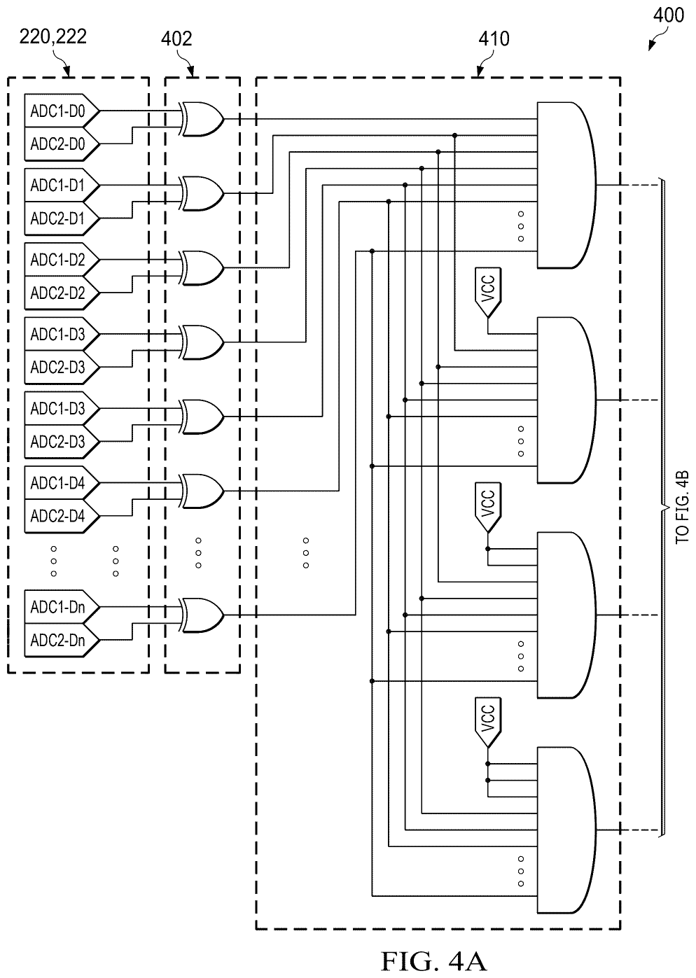

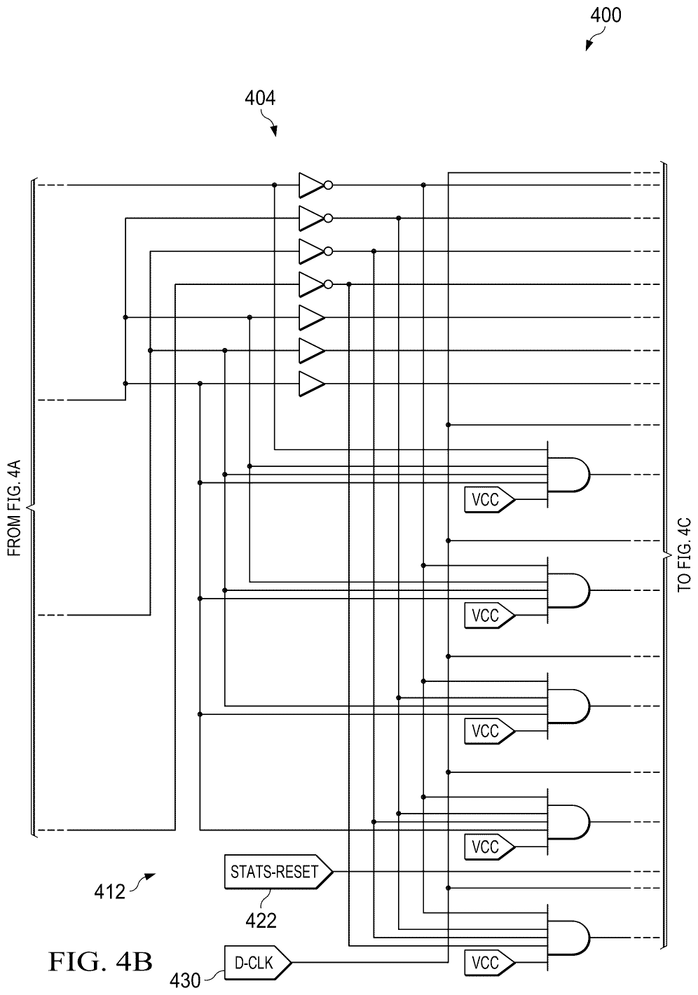

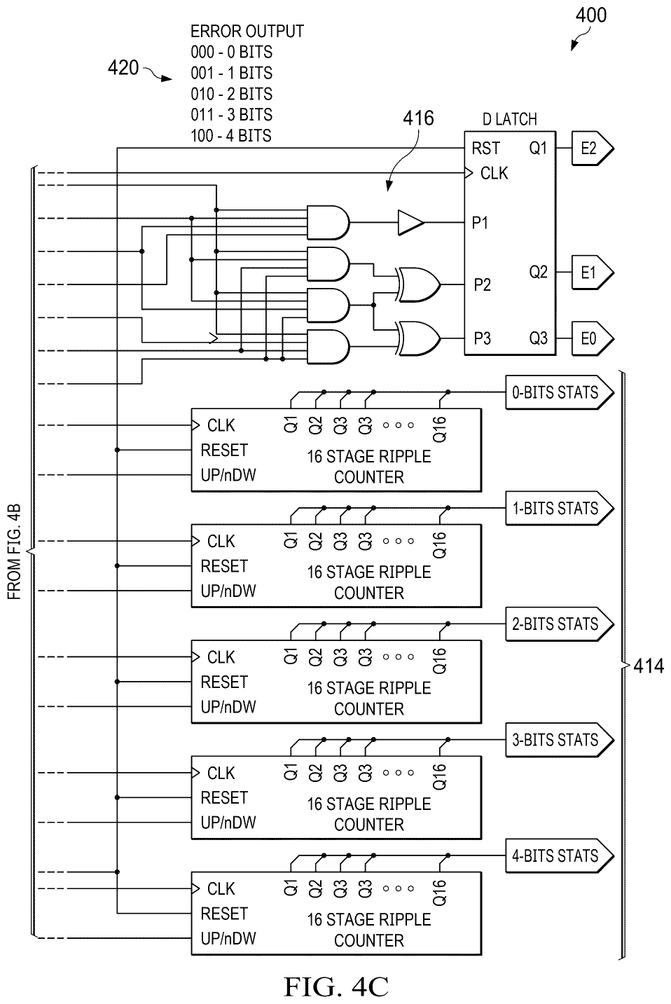

In some examples, system 100 may include error data analysis circuitry 140 to analyze invalid conversions 130, for example including counting invalid conversions 130 at respective bit levels and/or generating statistical data regarding invalid conversions 130 at respective bit levels, for example as discussed below with reference to FIGS. 3A-3C and FIGS. 4A-4C.

FIG. 2A shows an example system 200a for identifying analog-to-digital conversion errors. System 200a may represent an example implementation of system 100 in which ADCs 110 and 112 represent a pair of n-bit ADC IP blocks 210 and 212 as discussed below.

As shown, the example system 200a includes ADC circuitry 202 including a primary processing path including a first n-bit ADC block (IP block) 210 and a secondary processing path including a second n-bit ADC block (IP block) 212. Each of the first ADC block 210 and second ADC block 212 is supplied a reference voltage 214 (V_{REF}) at a respective REF+ input, which may define a maximum voltage the ADC circuitry 202 can convert. The first ADC block 210 may be configured to convert an analog input signal 206 (V_{ADC_IN}) to a first n-bit digital output signal 220, and the second ADC block 212 may be configured to convert an analog input signal complement 208, comprising a difference between the reference voltage 214 (V_{REF}) and the analog input signal 206 (V_{ADC_IN}), to a second n-bit digital output signal 222. Each of the first ADC block 210 and second ADC block 212 may comprise n-bit ADCs, for example 12 bit or 16 bit ADCs.

In the example shown in FIG. 2A, the first ADC block 210 has a first input VIN+_{ADC1} connected to the analog input signal 206 (V_{ADC_IN}) and a second input VIN−_{ADC1} connected to ground, wherein the first ADC block 210 evaluates (converts) the input signal 206 (V_{ADC_IN}), i.e., a differential voltage between the analog input signal 206 (V_{ADC_IN}) and ground, to generate the first n-bit digital output signal 220.

The second ADC block 212 has a first input VIN+_{ADC2} connected to the reference voltage 214 (V_{REF}) and a second input VIN−_{ADC2} connected to the analog input signal 206 (V_{ADC_IN}), wherein the second ADC block 212 evaluates (converts) the complement 208 of the input signal 206, i.e., a differential voltage between the reference voltage 214 (V_{REF}) and the analog input signal 206 (V_{ADC_IN}), to generate the second n-bit digital output signal 222. As shown, the analog input signal 206 (V_{ADC_IN}) may be adjusted by a respective programmable-gain amplifier (PGA) connected with each ADC block 210 and 212.

ADC circuitry 202 may include timing circuitry 250 to control the respective conversion timing (start of conversion) for each of the first and second ADC blocks 210 and 212, with each ADC block 210 and 212 operating at the acquisition (sampling) frequency of the analog input signal 206, for example 1 MHz. In this example, timing circuitry 250 includes a twice speed clock and a D Latch to feed the first and second ADC blocks 210 and 212 with opposite phase clocks (in quadrature), to thereby interlace the bit-level sampling of the analog input signal 206 (V_{ADC_IN}) by ADC blocks 210 and 212, and ensure temporal isolation between the operation of ADC blocks 210 and 212. In particular, the first ADC block 210 may be triggered by the rising sampling clock transition and the second ADC block 212 may be triggered by the falling clock transition, e.g., using a 50% clock duty cycle for continuous conversion. Timing circuitry 250 may utilize an end of conversion (EOC) flag to indicate when each ADC block 210, 212 completes a respective conversion.

For each sample of the analog input signal 206, the first ADC block 210 generates a respective n-bit first digital output signal 220 including bits ADC1-D0 (least significant bit) through ADC1-Dn (most significant bit) output via pins D0-Dn of the first ADC block 210, and similarly the second ADC block 212 generates a respective n-bit second digital output signal 222 including bits ADC2-D0 (least significant bit) through ADC2-Dn (most significant bit) output via pins D0-Dn of the second ADC block 212.

As discussed above regarding ADCs 110 and 112 shown in FIG. 1, when both ADC blocks 210 and 212 function properly (i.e., without conversion error), the first n-bit digital output signal 220 (i.e., the converted analog input signal 206) and the second n-bit digital output signal 222 (i.e., the converted analog input signal complement 108) are complementary to each other at the bit level. As shown in FIGS. 3A-3C and FIGS. 4A-4C discussed below, the outputs of ADC blocks 210 and 212 can be validated using an XOR operation (error detection circuitry) at the bit level, which may allow statistical evaluation of conversion errors (by error data analysis circuitry) with bit level granularity and in some examples without calculation. In addition, as the analog input values are different for the two ADC paths (i.e., V_{ADC_IN} input to the first ADC block 210, and V_{REF}−V_{ADC_IN} input to the second ADC block 212), nonlinearities and chain malfunctions can be detected. FIGS. 3A-3C and FIGS. 4A-4C discussed below show example error detection circuitry and associated error data analysis circuitry for identifying and analyzing conversion errors by ADC circuitry 202.

As shown, the same reference voltage (V_{REF}) applied at the REF+ input of each ADC block 210, 212 is used to define the second differential voltage (i.e., the analog input signal complement 208) converted by the second ADC block 212. In other examples, the reference voltage 214 (V_{REF}) used to define the second differential voltage (i.e., the analog input signal complement 208) may be independent from an ADC reference voltage applied at the REF+input of each ADC block 210, 212. In addition, in some examples, independent ADC reference voltages may be applied at the respective REF+ inputs of the first ADC block 210 and second ADC block 212, for example to detect potential faults associated with either ADC reference voltage.

In addition, as discussed above, ADC circuitry 202 may include V_{REF} adjustment circuitry 215 to dynamically adjust the reference voltage 214 (V_{REF}) to accommodate different input voltages V_{ADC_IN}, e.g., without having to adjust the gain of respective PGA(s) connected to ADC blocks 210, 212.

In some examples, the first and second ADC blocks 210 and 212 may be “identical” or “replicas” of each other, for example, formed with the same structure on the die, and may be oriented physically orthogonal to each other on the die, such that event upsets (e.g., induced currents, electrostatic discharges, or neutron or alpha particle upsets) will affect the ADC blocks 210 and 212 differently, thus resulting in detectable conversion errors.

As mentioned above, the first n-bit digital output signal 220 (output by the first ADC block 210) and second n-bit digital output signal 222 (output by the second ADC block 212) may be analyzed by error detection circuitry (e.g., comprising XOR gates) and/or error data analysis circuitry. Some examples may provide error detection and non-expiring error statistics (e.g., as shown in FIGS. 3A-3C discussed below), while other examples may provide error detection and rolling statistics (e.g., as shown in FIGS. 4A-4C discussed below). Both error detection and statistics circuitry may utilize logic gates and counters as accumulators for statistical results.

FIG. 2B shows an example system 200b for identifying analog-to-digital conversion errors. System 200b is similar to example system 200a discussed above, with like numbers referring to like parts, but using different timing circuitry 260 (instead of timing circuitry 250) for controlling the operational timing of ADC blocks 210 and 212.

Like timing circuitry 250 discussed above, timing circuitry 260 may control the respective conversion timing (start of conversion) for ADC blocks 210 and 212, with each ADC block 210 and 212 operating at the acquisition (sampling) frequency of the analog input signal 206 (e.g., 1 MHz), and ensure ADC block 210 and 212 operate in an interlaced (alternating) manner with temporal isolation. However, timing circuitry 260 may include controllable delay circuitry (e.g., controllable by a processor executing firmware or software) to dynamically control the delay (phase) between the operation of ADC blocks 210 and 212, for example to vary the delay between the respective clock signals for triggering ADC blocks 210 and 212. For example, timing circuitry 260 may introduce a phase jitter on either side or both sides of a 90 degree clock phase difference (quadrature) between the triggering of ADC blocks 210 and 212. Introducing such phase jitter or otherwise adjusting the delay (phase difference) over time may help identify certain perturbative effects, for example a repetitive noise at the same or multiple frequency as the acquisition frequency.

FIGS. 3A-3C show example circuitry 300 for analyzing digital output signals 220 and 222 from ADC blocks 210 and 212 of example system 200a or 200b shown in FIG. 2A or 2B, and computing cumulative error statistics. As shown, the first n-bit digital output signal 220 and second n-bit digital output signal 222 output by ADC blocks 210 and 212 are fed to an array of XOR gates (error detection circuitry) 302 that compare the digital output signals 220 and 222 at the bit level, with each bit of the n-bit digital output signal 220 being compared (using an XOR gate) with a corresponding bit of the n-bit digital output signal 222. Because the digital output signals 220 and 222 are complementary, if all XOR gates output a 1, no error is detected. However, if one or more XOR gates output a 0, a conversion error is detected for each bit having a corresponding XOR gate with a 0 output. The topology shown in FIGS. 3A-3C may generate statistics on data difference granularity from 0 bits to n bits.

As shown in FIGS. 3A-3C, the results of the error detection circuitry (XOR gates) 302 feed into error data analysis circuitry 304 for computing cumulative error statistics. In particular, output from the XOR gates 302 feed into multiple AND operations 310 for which different numbers of LSB bits of the output signals 220, 222 are disregarded (ignored).

At the end of each input sample conversion, for example at the D-CLK transition of the clock (CLK) input (indicated at D-CLK signal 330), logic circuitry 312 connected between the parallel AND operations 310 function to increment associated cumulative error counters 314. The different cumulative error counters 314 may be provided for counting errors of different bits of different 2ⁿ weights, wherein each cumulative error counter 314 counts a number of conversion errors identified for a respective bit of a respective 2ⁿ weight.

In addition, each AND result on the parallel AND operations 310 also feeds an error magnitude decoder 316 which, for example, outputs a three bit value indicated at 320. The statistical error information may be accumulated into the cumulative error counters 314 until such counters 314 are reset by a respective STATS-RESET signal 322. The cumulative error counters 314 will not overflow once the maximum value is reached. The illustrated topology may introduce no processing latency as data is updated at the end of each conversion cycle, such that delay is introduced only by the synthesis gates.

FIGS. 4A-4C show example circuitry 400 for analyzing digital output signals 220 and 222 from ADC blocks 210 and 212 of example system 200a or 200b shown in FIG. 2A or 2B, and computing rolling average error statistics. Circuitry 400 is generally similar to circuitry 300 shown in FIGS. 3A-3C and discussed above, but includes rolling average error counters 414 and associated logic circuitry 412 (rather than cumulative error counters 314 and associated logic circuitry 312) as discussed below.

As shown, the digital output signals 220 and 222 from ADC blocks 210 and 212 are fed to an array of XOR gates (error detection circuitry) 402 that compare the digital output signals 220 and 222 at the bit level. Again, if all XOR gates output a 1, no error is detected. However, if one or more XOR gates output a 0, a conversion error is detected for each corresponding bit.

As shown in FIGS. 4A-4C, the results of the error detection circuitry (XOR gates) 402 feed into error data analysis circuitry 404 for computing rolling average error statistics. In particular, output from the XOR gates 402 feed into multiple AND operations 410 for which different numbers of LSB bits are ignored. At the end of each input sample conversion, for example at the D-CLK transition of the clock (CLK) input (indicated at D-CLK signal 430), logic circuitry 412 connected between the parallel AND operations 410 function to increment associated rolling average counters 414. Each AND result on the parallel AND operations 410 also feeds an error magnitude decoder 416 which, for example, outputs a three bit value indicated at 420.

The logic circuitry 412 operates to increment each respective rolling average counter 414 if the corresponding AND result (from) is 0 and alternatively decrement the respective rolling average counter 414 if the AND result is 1. This incrementing/decrementing is performed for each level of error granularity: 0-bits errors, 1-bit errors, 2-bits errors, etc. The minimum and maximum values of the rolling average counters 414 will not overflow or underflow by a new end of cycle transaction once the minimum or maximum value are reached.

The statistical error information may be accumulated into the rolling average counters 414 until such counters 414 are reset by a respective STATS-RESET signal 422. Again, the illustrated topology may introduce no processing latency as data is updated at the end of each conversion cycle, such that delay is introduced only by the synthesis gates.

FIG. 5A illustrates another example system 500 for identifying analog-to-digital conversion errors. System 500 may represent an example implementation of system 100 in which ADCs 110 and 112 represent two ADC processes performed in succession by the same ADC block.

As shown, the example system 500 may include an ADC block 502, ADC state control circuitry 510, and a pair of digital output latches 516a (LATCH1) and 516b (LATCH2). The ADC state control circuitry 510 may include circuitry to utilize the ADC block 502 to perform both (a) a first ADC process to analyze an analog input signal 506 (V_{ADC_IN}), referred to below as “input signal conversion,” and (b) a second ADC process to analyze a complement of the analog input signal 506 (e.g., a differential voltage between a non-ground reference voltage V_{REF} and the analog input signal 506), referred to below as “input complement conversion. ”

More specifically, the ADC state control circuitry 510 may include ADC input control circuitry 512 (e.g., multiplexer) to switch between (a) a first ADC input configuration for performing an input signal conversion, which configuration includes connecting a first (positive) ADC input 530 to the analog input signal 506 and connecting a second (negative) ADC input 532 to ground, to thereby convert a first differential voltage between the analog input signal 506 and ground, and (b) a second ADC input configuration for performing an input complement conversion, which configuration includes connecting the first ADC input 530 to the non-ground reference voltage V_{REF} and connecting the second ADC input 532 to the analog input signal 503, to thereby convert a second differential voltage between the reference voltage V_{REF} and the analog input signal 506 to the second digital output signal, i.e., the complement of the analog input signal 506.

In the illustrated example, the ADC input control circuitry 512 (e.g., multiplexer) may be controlled by a dual conversion state machine 514. The dual conversion state machine 514 may also control the digital output latches 516a (LATCH1) and 516b (LATCH2) to thereby generate an first n-bit digital output signal 520 resulting from the input signal conversion and a separate second n-bit digital output signal 522 resulting from the input complement conversion, which output signals 520 and 522 may be fed to respective error detection circuitry and error data analysis circuitry as discussed above.

FIG. 5B shows an example signal diagram 550 of an example operation of system 500. Referring to FIGS. 5A and 5B collectively, on the rising clock (A), the state machine 514 switches (D) the multiplexor 512 to a first position that connects the positive ADC input 530 to the input voltage V_{ADC_IN}, and connects the negative ADC input 532 to ground. After the ADC inputs 530, 532 stabilize (short delay), a first ADC conversion is started (B) and the state machine 514 waits for the end of conversion (EOC) flag (C), then transfers the digital output data to LATCH1 516a (I), indicated by the first n-bit digital output signal 520.

On the falling clock (E), the state machine 514 switches (H) to a second position that connects the positive ADC input 530 to the reference voltage V_{REF} and connects the negative ADC input 532 to the input voltage V_{ADC_IN}. After the ADC inputs 530, 532 stabilize (short delay), a second ADC conversion is started (F) and the state machine 514 waits for the end of conversion (EOC) flag (C), then transfers the digital output data to LATCH2 516b (J), indicated by the second n-bit digital output signal 520. After LATCH 2 outputs (522) are stabilized, the falling of the LATCH 2 signal (K) generates a global EOC signal (L) that indicates the end of the conversion cycle. As a result, the 520 will reflect the voltage conversion and 522 will reflect the result of complementary conversion.

In this manner, the output signal 520 represents the conversion of the input voltage V_{ADC_IN}, and the output signal 520 represents the conversion of the input voltage complement (V_{REF}−V_{ADC_IN}). As discussed above, the first and second output signals 520 and 522 may be fed to respective error detection circuitry and error data analysis circuitry as discussed above, for example including the example circuitry shown in FIGS. 3A-3C or FIGS. 4A-4C and discussed above.

Although example embodiments have been described above, other variations and embodiments may be made from this disclosure without departing from the spirit and scope of these embodiments.

1. A system, comprising:
analog-to-digital converter (ADC) circuitry to:
convert an analog input signal to a first digital output signal; and
convert a complement of the analog input signal to a second digital output signal, wherein the complement of the analog input signal comprises a difference between a reference voltage and the analog input signal; and
error detection circuitry to identify an invalid conversion of the analog input signal based on the first digital output signal and the second digital output signal.

2. The system of claim 1, wherein the ADC circuitry comprises:
a first ADC block to convert the analog input signal to the first digital output signal; and
a second ADC block, connected in parallel with the first ADC block, to convert the complement of the analog input signal to the second digital output signal.

3. The system of claim 2, wherein:
the first ADC block has a first ADC input and a second ADC input, and the second ADC block has a first ADC input and a second ADC input;
the first ADC input of the first ADC block is connected to the analog input signal, and the second ADC input of the first ADC block is connected to ground, wherein the first ADC block is configured to convert a first differential voltage between the analog input signal and ground to the first digital output signal; and
the first ADC input of the second ADC block is connected to a non-ground reference voltage, and the second ADC input of the second ADC block is connected to the analog input signal, wherein the second ADC block is configured to convert a second differential voltage between the non-ground reference voltage and the analog input signal to the second digital output signal, the second differential voltage defining the complement of the analog input signal.

4. The system of claim 2, wherein the first ADC block and the second ADC block are arranged physically orthogonal to each other.

5. The system of claim 1, wherein the ADC circuitry comprises an ADC block to (a) perform a first conversion to convert the analog input signal to the first digital output signal and (b) in series with the first conversion, perform a second conversion to convert the complement of the analog input signal to the second digital output signal.

6. The system of claim 5, wherein:
the ADC block has a first ADC input and a second ADC input;
wherein the ADC circuitry comprises circuitry to switch between:
a first ADC input configuration for the first conversion, wherein the first ADC input configuration includes connecting the first ADC input to the analog input signal and connecting the second ADC input to ground, wherein the first conversion comprises converting a first differential voltage between the analog input signal and ground; and
a second ADC input configuration for the second conversion, wherein the second ADC input configuration includes connecting the first ADC input to a non-ground reference voltage and connecting the second ADC input to the analog input signal, wherein the second conversion comprises converting a second differential voltage between the non-ground reference voltage and the analog input signal to the second digital output signal, the second differential voltage defining the complement of the analog input signal.

7. The system of claim 6, wherein the ADC circuitry comprises a multiplexer to switch between the first ADC input configuration for the first conversion and the second ADC input configuration for the second conversion.

8. The system of claim 1, wherein the error detection circuitry comprises circuitry to:
perform a bit-level conversion analysis including comparing respective bits of the first digital output signal with corresponding bits of the second digital output signal; and
identify the invalid conversion of the analog input signal based on the bit-level conversion analysis.

9. The system of claim 1, wherein the error detection circuitry comprises an XOR circuitry to compare respective bits of the first digital output signal with corresponding bits of the second digital output signal, wherein an output of 0 from the XOR circuitry indicates a bit-level conversion error.

10. The system of claim 1, wherein the error detection circuitry comprises circuitry to:
perform a bit-level conversion analysis for multiple bits of the first digital output signal and multiple corresponding bits of the second digital output signal, wherein the bit-level conversion analysis for a respective bit of the multiple bits of the first digital output signal includes:
comparing the respective bit of the first digital output signal with a corresponding bit of the second digital output signal; and
based on the comparison, identifying a bit-level conversion error if a value of the respective bit of the first digital output signal is the same as a value of the corresponding bit of the second digital output signal; and
identify the invalid conversion of the analog input signal based on the bit-level conversion analysis.

11. The system of claim 10, wherein the error detection circuitry comprises circuitry to, when performing the bit-level conversion analysis, disregard a defined number of least significant bits (LSB) of the first digital output signal and corresponding bits of the second digital output signal.

12. The system of claim 10, wherein the error detection circuitry comprises an XOR circuitry to compare respective bits of the first digital output signal with corresponding bits of the second digital output signal.

13. The system of claim 1, wherein the ADC circuitry comprises circuitry to dynamically adjust the reference voltage.

14. The system of claim 1, wherein:
the first digital output signal comprises a first n-bit signal;
the second digital output signal comprises a second n-bit signal; and
the error detection circuitry comprises circuitry to:
identify a k-bit conversion error based on the first digital output signal and the second digital output signal;
determine whether the k-bit conversion error exceeds a defined error threshold; and
identify the invalid conversion of the analog input signal based on determining the k-bit conversion error exceeds the defined error threshold.

15. The system of claim 1, comprising circuitry to implement a time delay between converting the analog input signal to the first digital output signal and converting the complement of the analog input signal to the second digital output signal.

16. The system of claim 15, wherein the time delay is a half period of a sampling clock cycle.

17. The system of claim 1, comprising multiple error counters for multiple different bits of different 2ⁿ weights, wherein a respective error counter counts a number of conversion errors identified for a respective bit of a respective 2ⁿ weight.

18. A method, comprising:
receiving an analog input signal at analog-to-digital converter (ADC) circuitry;
performing a first conversion, by the ADC circuitry, to convert the analog input signal to a first digital output signal;
performing a second conversion, by the ADC circuitry, to convert a complement of the analog input signal to a second digital output signal, wherein the complement of the analog input signal comprises a difference between a reference voltage and the analog input signal; and
identifying, by error detection circuitry, an invalid conversion of the analog input signal based on the first digital output signal and the second digital output signal.

19. The method of claim 18, wherein the ADC circuitry includes a first ADC block and a second ADC block connected in parallel with the first ADC block; and
the method comprises:
performing the first conversion by the first ADC block to convert the analog input signal to the first digital output signal; and
performing the second conversion by the second ADC block to convert a second ADC block to convert the complement of the analog input signal to the second digital output signal.

20. The method of claim 18, wherein:
the ADC circuitry includes a first ADC block and a second ADC block connected in parallel with the first ADC block;
the first ADC block has a first ADC input and a second ADC input, and the second ADC block has a first ADC input and a second ADC input;
the first ADC input of the first ADC block is connected to the analog input signal, and the second ADC input of the first ADC block is connected to ground, wherein performing the first conversion by the first ADC block comprises the first ADC block converting a first differential voltage between the analog input signal and ground to the first digital output signal; and
the first ADC input of the second ADC block is connected to a non-ground reference voltage, and the second ADC input of the second ADC block is connected to the analog input signal, wherein performing the second conversion by the second ADC block comprises the second ADC block converting a second differential voltage between the non-ground reference voltage and the analog input signal to the second digital output signal, the second differential voltage defining the complement of the analog input signal.

21. The method of claim 18, wherein the ADC circuitry comprises an ADC block, and wherein the method comprises:
the ADC block performing the first conversion to convert the analog input signal to the first digital output signal;
in series with the first conversion, the ADC block performing the second conversion to convert a second ADC block to convert the complement of the analog input signal to the second digital output signal.

22. The method of claim 18, wherein identifying the invalid conversion of the analog input signal comprises:
performing a bit-level conversion analysis including comparing respective bits of the first digital output signal with corresponding bits of the second digital output signal; and
identifying the invalid conversion of the analog input signal based on the bit-level conversion analysis.

23. The method of claim 18, comprising:
using an XOR circuitry to compare respective bits of the first digital output signal with corresponding bits of the second digital output signal; and
identifying a bit-level conversion error based on an output of 0 from the XOR circuitry.

24. A system, comprising:
a first analog-to-digital converter (ADC) having a first ADC input and a second ADC input;
wherein the first ADC input of the first ADC block is connected to an analog input signal, and the second ADC input of the first ADC block is connected to ground, wherein the first ADC block is configured to convert a first differential voltage between the analog input signal and ground to a first digital output signal;
a second ADC block having a first ADC input and a second ADC input;
wherein the first ADC input of the second ADC block is connected to a non-ground reference voltage, and the second ADC input of the second ADC block is connected to the analog input signal, wherein the second ADC block is configured to convert a second differential voltage between the non-ground reference voltage and the analog input signal to a second digital output signal; and
error detection circuitry to identify an invalid conversion of the analog input signal based on the first digital output signal and the second digital output signal.

25. The system of claim 24, wherein the error detection circuitry comprises circuitry to:
perform a bit-level conversion analysis including comparing respective bits of the first digital output signal with corresponding bits of the second digital output signal; and
identify the invalid conversion of the analog input signal based on the bit-level conversion analysis.

26. The system of claim 25, wherein the error detection circuitry comprises an XOR circuitry to compare respective bits of the first digital output signal with corresponding bits of the second digital output signal, wherein an output of 0 from the XOR circuitry indicates a bit-level conversion error.

27. The system of claim 24, wherein the error detection circuitry comprises circuitry to:
perform a bit-level conversion analysis for multiple bits of the first digital output signal and multiple corresponding bits of the second digital output signal, wherein the bit-level conversion analysis for a respective bit of the multiple bits of the first digital output signal includes:
comparing the respective bit of the first digital output signal with a corresponding bit of the second digital output signal; and
based on the comparison, identifying a bit-level conversion error if a value of the respective bit of the first digital output signal is the same as a value of the corresponding bit of the second digital output signal; and
identify the invalid conversion of the analog input signal based on the bit-level conversion analysis.
